(19) United States
(12) Patent Application Publication
(10) Pub. No.: US 2012/0327574 A1
(43) Pub. Date: Dec. 27, 2012

(54) ELECTRONIC COMPONENT

(75) Inventors: Hideaki SAKAGUCHI, Nagano (JP); Akinori Shiraishi, Nagano (JP)

(73) Assignee: SHINKO ELECTRIC INDUSTRIES CO., LTD., Nagano-shi (JP)

(21) Appl. No.: 13/528,074

(22) Filed: Jun. 20, 2012

(30) Foreign Application Priority Data
Jun. 21, 2011 (JP) 2011-136971

(51) Int. Cl. H05K 7/00

(52) U.S. Cl. 361/679.01

(57) ABSTRACT

At least one embodiment provides an electronic component including: connection electrodes; and flexible electrode terminals connected to the respective connection electrodes so that spaces are formed under the respective flexible electrode terminals, each flexible electrode terminal having a main body and a connection projection provided on a top surface of the main body, each flexible electrode terminal being elastically deformable when receiving pressure.

### CROSS-REFERENCE TO RELATED APPLICATION(S)

This application claims priority/priorities from Japanese Patent Application No. 2011-136971 filed on Jun. 21, 2011, the entire contents of which are incorporated herein by reference.

### FIELD

The present invention relates to electronic components such as a mounting board, an interposer and a semiconductor chip.

### BACKGROUND

Conventionally, with the miniaturization, thickness reduction and performance enhancement of electronic apparatus, mounting structures in which a semiconductor chip is flip-chip-connected to a mounting board have come to be employed widely. For example, the solder bumps of a semiconductor chip may be flip-chip-connected to the connection electrodes of a mounting board, and the space under the semiconductor chip may be filled with underfill resin.

Further, the semiconductor chip may be flip-chip-connected to an interposer, and the interposer may be connected to the mounting board. For example, JP-2008-252053-A, JP-2005-183924-A and JP-H11-195676-A relate to such technique.

The thermal expansion coefficient of such semiconductor chip (made of silicon) is much different from that of such mounting board (made of a glass epoxy resin). Therefore, in a heating process for mounting the semiconductor chip, residual stress tends to be concentrated at the joining portions due to thermal stress.

As a result, a joining portion of the semiconductor chip and the mounting board or elements of the semiconductor chip may be broken, that is, the reliability of the electrical connections is insufficient. A similar problem arises also when the semiconductor chip is connected to the mounting board via the interposer of silicon.

### SUMMARY

One aspect of the present invention provides an electronic component including: connection electrodes; and flexible electrode terminals connected to the respective connection electrodes so that spaces are formed under the respective flexible electrode terminals, each flexible electrode terminal having a main body and a connection projection provided on a top surface of the main body, each flexible electrode terminal being elastically deformable when receiving pressure.

The electronic component (mounting board, interposer, or semiconductor chip) according to the invention has the flexible electrode terminals in each of which the connection projection is provided on the top surface of the main body.

For example, where an interposer to which a semiconductor chip is flip-chip-connected is connected to the flexible electrode terminals that are provided in a mounting board, even if thermal stress occurs at the time of mounting, the stress can be dispersed because the flexible electrode terminals of the mounting board are warped through elastic deformation.

Since each flexible electrode terminal has the connection projection, stress occurring at the time of mounting can be concentrated at the connection projection. Therefore, the stress can easily be dispersed because it is transmitted to the main body efficiently via the connection projection and the main body is thereby warped.

Therefore, residual stress occurring in the joining portions of the mounting board and the interposer can be weakened. As a result, destruction of a joining portion of the mounting board and the interposer is prevented and the reliability of a semiconductor device can thereby be increased.

### BRIEF DESCRIPTION OF DRAWINGS

FIGS. 1A-2 cross-sectionally illustrates preliminary items.

FIGS. 3A-4C illustrate a manufacturing method of a mounting board (electronic component) according to a first embodiment.

FIG. 5A cross-sectionally illustrates a flexible electrode terminal according to the first embodiment, and FIGS. 5B-5D illustrate example plan-view shapes thereof.

FIG. 6 cross-sectionally illustrates the mounting board according to the first embodiment.

FIGS. 7A and 7B cross-sectionally illustrate an interposer on which semiconductor chips are flip-chip-connected.

FIG. 8 cross-sectionally illustrates a semiconductor device in which the semiconductor-chips-mounted interposer shown in FIG. 7B is connected to the mounting board shown in FIG. 6.

FIG. 9 illustrates a state where spaces are filled with underfill resin.

FIG. 10 cross-sectionally illustrates a semiconductor device in which semiconductor chips are connected to the mounting board shown in FIG. 6.

FIG. 11 illustrates a state where a space is filled with underfill resin.

FIG. 12 cross-sectionally illustrates an interposer according to the first embodiment.

FIG. 13 cross-sectionally illustrates a semiconductor chip according to the first embodiment.

FIGS. 14A and 14B cross-sectionally illustrate flexible electrode terminals according to modifications of the first embodiment, respectively.

FIGS. 15-17 cross-sectionally illustrate a mounting board, an interposer, and a semiconductor chip according to a second embodiment, respectively.

FIGS. 18A and 18B cross-sectionally illustrate flexible electrode terminals according to modifications of the second embodiment, respectively.

### DETAILED DESCRIPTION

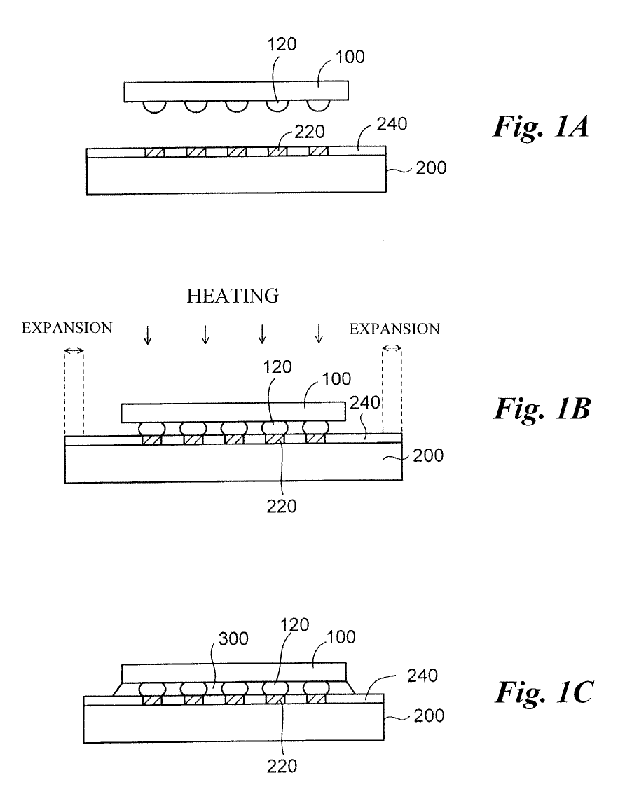

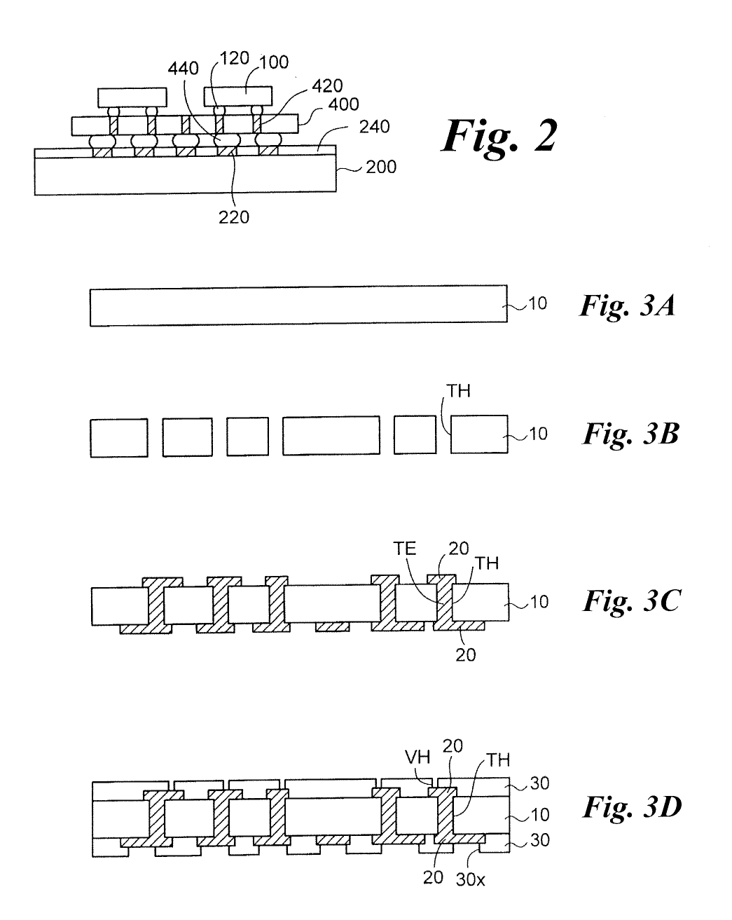

FIGS. 1A-2 cross-sectionally illustrates preliminary items.

As shown in FIG. 1A, first, a semiconductor chip 100 and a mounting board 200 (package board) are prepared. The bottom surface of the semiconductor chip 100 is formed with solder bumps 120.

The mounting board 200 is made of a glass epoxy resin and its top surface is formed with a solder resist layer 240 and connection electrodes 220 exposed therefrom.

Then, as shown in FIG. 1B, solder is applied to the connection electrodes 220 of the mounting board 200, and the solder bumps 120 of the semiconductor chip 100 are placed over the respective connection electrodes 220 of the mounting board 200. Then, reflow soldering is performed by melting the solder by heating it, whereby the semiconductor chip 100 is flip-chip-connected to the mounting board 200.

In the case of lead-free (Pb-free) solder such as tin-silver-copper (Sn—Ag—Cu) solder, heating needs to be performed at a relatively high temperature (about 220° C. to 250° C.).

When the semiconductor chip 100 is made of a silicon, a thermal expansion coefficient thereof is 3 to 4 ppm/° C. On the other hand, when the mounting board 200 is made of a glass epoxy resin, a thermal expansion coefficient thereof is 18 ppm/° C. In this case, there is a large difference between these two thermal expansion coefficients.

Therefore, as shown in FIG. 1B, in the heating process for the reflow soldering, the mounting board 200 having the larger thermal expansion coefficient is expanded more than the semiconductor chip 100. Then, after the temperature is lowered to room temperature, the space under the semiconductor chip 100 is filled with an underfill resin layer 300.

When the temperature is lowered to room temperature, the semiconductor chip 100 and the mounting board 200 which have been expanded because of thermal expansion return to their original states.

Here, residual stress is concentrated at the joining portions of the semiconductor chip 100 and the mounting board 200, and the joining portions may be broken.

In other words, a connection portion on the semiconductor chip 100 side, a connection portion on the mounting board 200 side, or a solder bump 120 may be broken to cause a conduction failure. Or internal elements of the semiconductor chip 100 may be broken due to residual stress.

Therefore, the mismatch between the thermal expansion coefficients of the semiconductor chip 100 and the mounting board 200 may deteriorate the reliability of flip-chip-connection, especially when the area of the semiconductor chip 100 is large (to 15 to 20 mm square) and the height of the solder bumps 120 is small.

FIG. 2 illustrates a state where semiconductor chips 100 are flip-chip-connected to a mounting board 200 via a silicon interposer 400. The silicon interposer 400 has through-electrodes 420 for establishing electrical continuity between its top surface and bottom surface. Solder bumps 120 of each semiconductor chip 100 are flip-chip-connected to electrodes formed on the top surface of the silicon interposer 400.

Solder bumps 440 of the silicon interposer 400 are connected to connection electrodes 220 of the mounting board 200 by reflow soldering.

Also when the silicon interposer 400 is used, there is a mismatch between the thermal expansion coefficients of the silicon interposer 400 and the mounting board 200, and thus, joining portions therebetween may be broken due to residual stress.

The above-described problems can be solved by using an interposer according to embodiment which will be described below.

### Embodiment 1

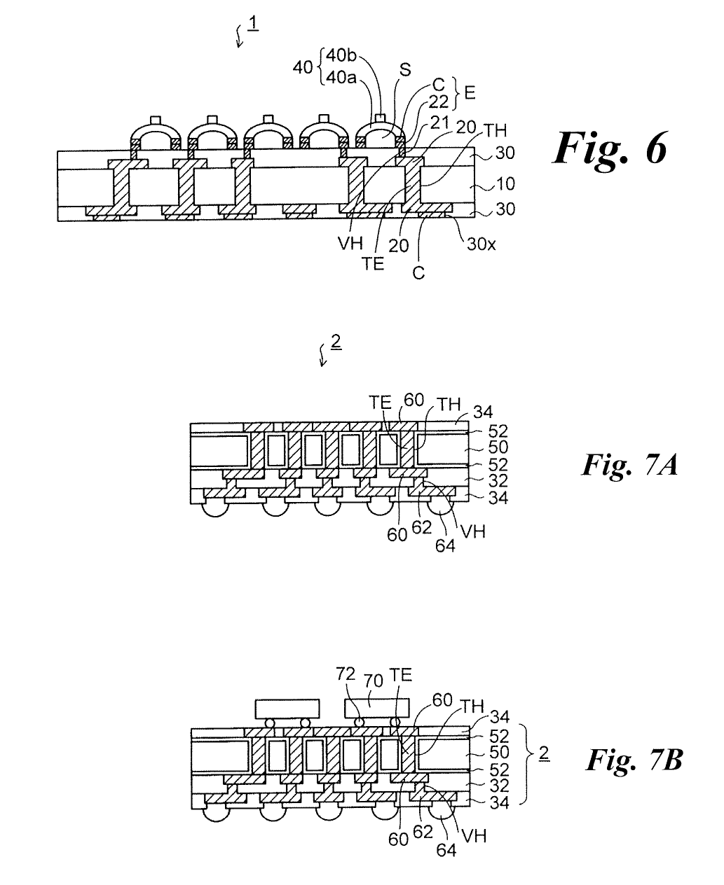

FIGS. 3A-5D illustrate a manufacturing method of a mounting board (electronic component) according to the first embodiment. FIG. 6 cross-sectionally illustrates the mounting board according to the first embodiment.

The first embodiment is adaptable to electronic components, such as a mounting board, an interposer and a semiconductor chip. First, a description will be made of a method for forming flexible electrode terminals having a stress reducing function on a mounting board. The mounting board is used as, for example, a wiring board of a semiconductor package.

First, as shown in FIG. 3A, a base board 10 is prepared. The base board (core board) 10 is an organic board containing a resin such as a glass epoxy resin.

Then, as shown in FIG. 3B, through-holes TH are formed through the base board 10 so as to reach its top surface and bottom surface by drilling, for example.

Then, as shown in FIG. 3C, the through-holes TH of the base board 10 are filled with respective through-electrodes TE, and first wiring layers 20 are formed on the two respective surfaces of the base board 10 so as to be connected to each other by the through-electrodes TE.

One example method for forming the through-electrodes TE and the first wiring layers 20 is to form metal layers made of copper or the like inside the through-holes TH and on both surfaces of the base board 10 by plating, and then pattern the metal layers on both surfaces of the base board 10 by photolithography and etching.

Alternatively, a double-sided copper-clad laminate may be used. First wiring layers 20 formed on the two respective surfaces are connected to each other by through-hole plating layers formed on the side surfaces of through-holes TH. The spaces inside the respective through-holes TH are filled with resin.

Then, as shown in FIG. 3D, a protective insulating layer 30 is formed on the top surface of the base board 10 to have via holes VH which expose respective connection portions of the upper first wiring layer 20. Likewise, another protective insulating layer 30 is formed on the bottom surface of the base board 10 to have openings 30x which expose respective connection portions of the lower first wiring layer 20.

Each protective insulating layer 30 is formed by sticking a photosensitive resin film to the base board 10, and then forming via holes VH or openings 30x by photolithography. Alternatively, a liquid resin may be applied to the base board 10, and then, via holes VH or openings 30x may be formed by photolithography. Still alternatively, a resin film may be formed on the base board 10, and then, via holes VH or openings 30x may be formed by laser-processing. It is preferable that each protective insulating layer 30 be made of a solder resist.

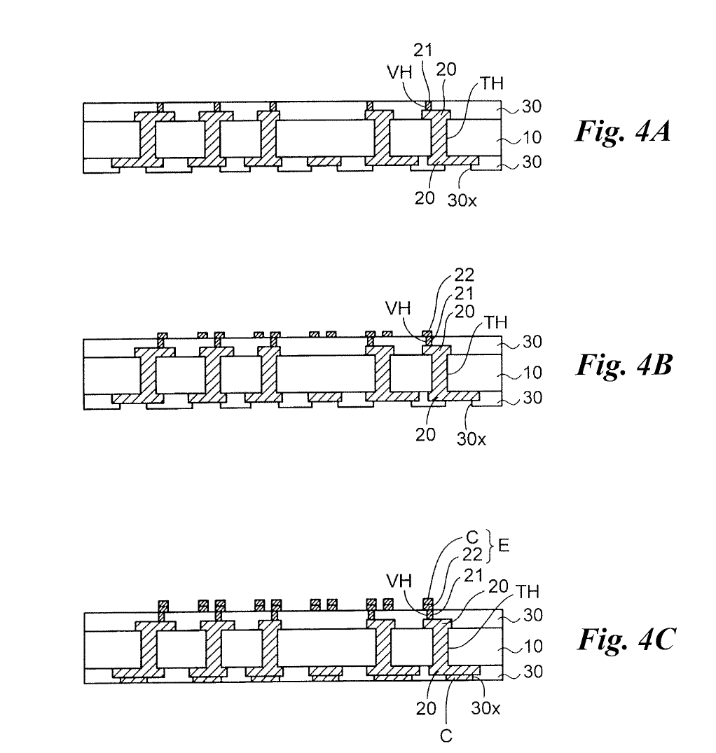

Then, as shown in FIG. 4A, the via holes VH of the upper protective insulating layer 30 is filled with respective metal layers made of copper or the like by electroless plating, thereby obtaining via conductors 21 which are connected to the upper first wiring layer 20.

Alternatively, via conductors 21 may be formed through the respective via holes VH of the upper protective insulating layer 30 by electrolytic plating. In this case, via conductors 21 are obtained by forming a seed layer on the top surface of the base board 10, filling the via holes VH with a metal layer (electrolytic plating layer), and polishing the metal layer until the upper protective insulating layer 30 is exposed.

Then, as shown in FIG. 4B, a conductor pattern layer 22 (second wiring layer) is formed on the upper protective insulating layer 30 so as to be connected to the via conductors 21. The conductor pattern layer 22 may be either island-shaped pad electrodes or patterns each including an extending wiring and a pad electrode connected to its one end.

The conductor pattern layer 22 is formed by a semi-additive method, for example. Specifically, first, a seed layer (not shown) made of copper or the like is formed on the upper protective insulating layer 30 and the via conductors 21 by electroless plating or sputtering.

Then, a plating resist layer (not shown) is formed to have openings for forming a conductor pattern layer 22. Then, metal plating layers (not shown) made of copper or the like are formed in the respective openings of the plating resist layer by electrolytic plating using the seed layer as a plating electricity supply path.

After the plating resist layer is removed, the seed layer is etched using the metal plating layers as a mask, thereby obtaining the conductor pattern layer 22 formed by portions of the seed layer and the metal plating layers.

Then, as shown in FIG. 4C, a contact layer C is formed on respective connection portions of the conductor pattern layer 22. The contact layer C is formed by sequentially forming a nickel layer and a gold layer on the conductor pattern layer 22 by electroless plating.

Alternatively, a contact layer C may be formed by forming a solder layer on the conductor pattern layer 22 by electrolytic plating. Thus, connection electrodes E are formed of the conductor pattern layer 22 and the contact layer C formed thereon.

Then, a contact layer C is formed on the respective connection portions of the lower first wiring layer 20.

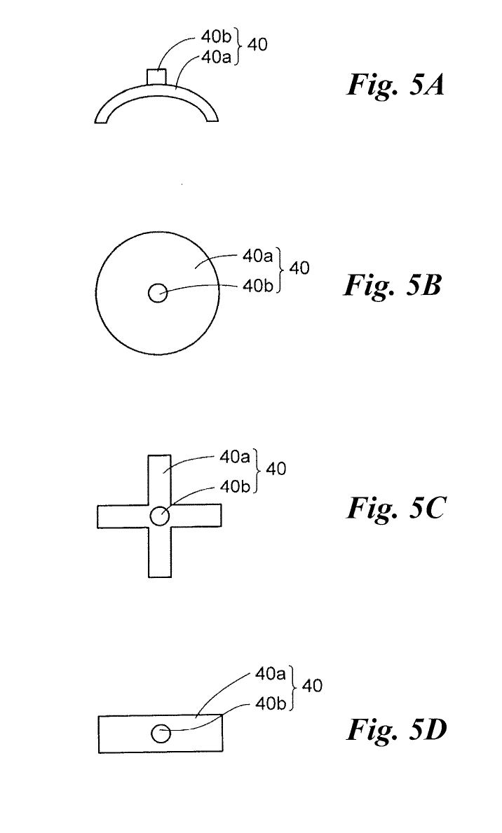

Then, as shown in FIG. 5A, flexible electrode terminals 40 (electrode components) are prepared. For example, the flexible electrode terminals 40 may be previously formed. Each flexible electrode terminal 40 has a dome-like bulge 40a (main body) and a connection projection 40b which projects upward from the center of the top surface of the bulge 40a.

Each flexible electrode terminal 40 is made of a metal material that is deformed elastically when receiving pressure. As a result, when thermal stress occurs at the time of mounting, each flexible electrode terminal 40 is warped through elastic deformation, thereby absorbing the stress.

Example metal materials capable of realizing such a function of the flexible electrode terminals 40 are copper, nickel, and spring materials such as phosphor bronze, beryllium copper, and titanium copper. For example, each flexible electrode terminal 40 is formed as a single body by pressing a metal plate made of such a material.

Another electronic component such as an interposer or a semiconductor chip is connected to the connection projections 40b of the flexible electrode terminals 40. Since each flexible electrode terminal 40 has the dome-like bulge 40a as the main body, it can easily warp and thereby move downward, laterally, or obliquely downward.

Since the connection projection 40b is provided on the bulge 40a, stress occurring at the time of mounting can be concentrated at the connection projection 40b. Therefore, stress occurring at the time of mounting is transmitted efficiently to the bulge 40a via the connection projection 40b so as to be dispersed by warping of the bulge 40a.

FIGS. 5B to 5D illustrate example plan-view shapes of the flexible electrode terminal 40. In FIG. 5B, a connection projection 40b is provided at the center of the top surface of a circular bulge 40a. In FIG. 5C, a connection projection 40b is provided at the center of the top surface of a cruciform bulge 40a. In FIG. 5D, a connection projection 40b is provided at the center of the top surface of a long and narrow, rectangular (band-shaped) bulge 40a.

Then, as shown in FIG. 6, end portions of the bulges 40a of the flexible electrode terminals 40 are connected to the connection electrodes E of the structure of FIG. 4C. The flexible electrode terminals 40 are connected to the connection electrodes E such that spaces S are formed under the respective flexible electrode terminals 40.

Example manners of connection between each flexible electrode terminal 40 and a connection electrode E are solder connection, conductive paste connection, and various kinds of metal connection such as gold (Au)-gold connection, gold-tin (Sn) connection, and gold-indium (In) connection.

Each flexible electrode terminal 40 and a connection electrode E are connected to each other by forming, for example, metal layers of a prescribed one of the above combinations on their surfaces. For example, each flexible electrode terminal 40 and a connection electrode E are connected to each other after forming a metal layer or a solder layer on the entire outer surface of each flexible electrode terminal 40 as an outermost layer, and then subjecting it to surface treatment. Alternatively, each flexible electrode terminal 40 and a connection electrode E may be gold-tin-connected via a gold/tin sheet.

As a result, the mounting board 1 (electronic component) according to the first embodiment is obtained.

As shown in FIG. 6, in the mounting board 1 according to the first embodiment, the through-holes TH are formed through the base board 10, and the through-electrodes TE are formed to fill the respective through-holes TH and to connect the first wiring layers 20 on the two respective surfaces of the base board 10.

The upper protective insulating layer 30 is formed on the top surface of the base board 10, and the via holes VH are formed through the upper protective insulating layer 30 so as to reach the upper first wiring layer 20. The via holes VH are filled with the respective via conductors 21 which are connected to the upper first wiring layer 20.

The connection electrodes E are formed on the upper protective insulating layer 30 so as to be connected to the respective via conductors 21. Each connection electrode E includes the conductor pattern layer 22 and the contact layer C formed thereon.

The lower protective insulating layer 30 is formed on the bottom surface of the base board 10 to have the openings 30x which expose the respective connection portions of the lower first wiring layer 20. The contact layer C is formed on the connection portions of the lower first wiring layer 20.

The flexible electrode terminals 40 are connected to the respective connection electrodes E such that the spaces S are formed between the respective flexible electrode terminals 40 and the top surface of the base board 10. Each flexible electrode terminal 40 includes the bulge 40a (main body) which bulges upward and the connection projection 40b which is provided at the center of the top surface of the bulge 40a. Having the space S below, the bulge 40a of each flexible electrode terminal 40 can be warped and deformed when receives pressure.

Next, an interposer and semiconductor chips to be connected to the mounting board 1 shown in FIG. 6 will be described.

As shown in FIG. 7A, in an interposer 2, through-holes TH are formed through a silicon substrate 50, and an insulating layer 52 is formed on both surfaces of the silicon substrate 50 and the inner surfaces of the through-holes TH. The through-holes TH are filled with the respective through-electrodes TE.

First wiring layers 60 are formed on the two respective surfaces of the silicon substrate 50 so as to be connected to each other by the through-electrodes TE. A protective insulating layer 34 is formed on the top surface of the silicon substrate 50 so as to expose connection portions of the upper first wiring layer 60.

An interlayer insulating layer 32 is formed on the bottom surface of the silicon substrate 50 so as to cover the lower first wiring layer 60. Via holes VH are formed through the interlayer insulating layer 32 so as to reach the lower first wiring layer 60. A second wiring layer 62 is formed on the bottom surface of the interlayer insulating layer 32 so as to be connected to the lower first wiring layer 60 by the via holes VH.

Another protective insulating layer 34 is formed on the bottom surface of the interlayer insulating layer 32 so as to expose connection portions of the second wiring layer 62. External connection terminals 64 are formed on the respective connection portions of the second wiring layer 62.

That is, the first wiring layer 60 and the second wiring layer 62 realize pitch conversion from the narrow pitch of the upper first wiring layer 60 corresponding to a semiconductor chip to the wide pitch corresponding to the connection electrodes E of the mounting board 1. For example, the pitches of the upper first wiring layer 60 and the second wiring layer 62 are set at 150 μm and 300 to 500 μm, respectively.

Although the interposer 2 employs the silicon substrate 50, a glass substrate may be used in place of the silicon substrate 50. In this case, the insulating layer 52 is omitted.

Then, as shown in FIG. 7B, semiconductor chips 70 (LSI chips) the bottom surface of each of which is formed with solder bumps 72 are prepared. The semiconductor chips 70 are obtained by cutting a silicon wafer on which various elements such as transistors are formed.

Then, solder is applied to the upper first wiring layer 60 of the interposer 2 shown in FIG. 7A, the solder bumps 72 of each semiconductor chip 70 are placed over the upper first wiring layer 60 of the interposer 2, and reflow soldering is performed by heating. As a result, the semiconductor chips 70 are flip-chip-connected to the interposer 2.

Since the interposer 2 (made of silicon) and the semiconductor chips 70 (made of silicon) have the same thermal expansion coefficient, thermal stress is reduced and high reliability of the joining portions is secured.

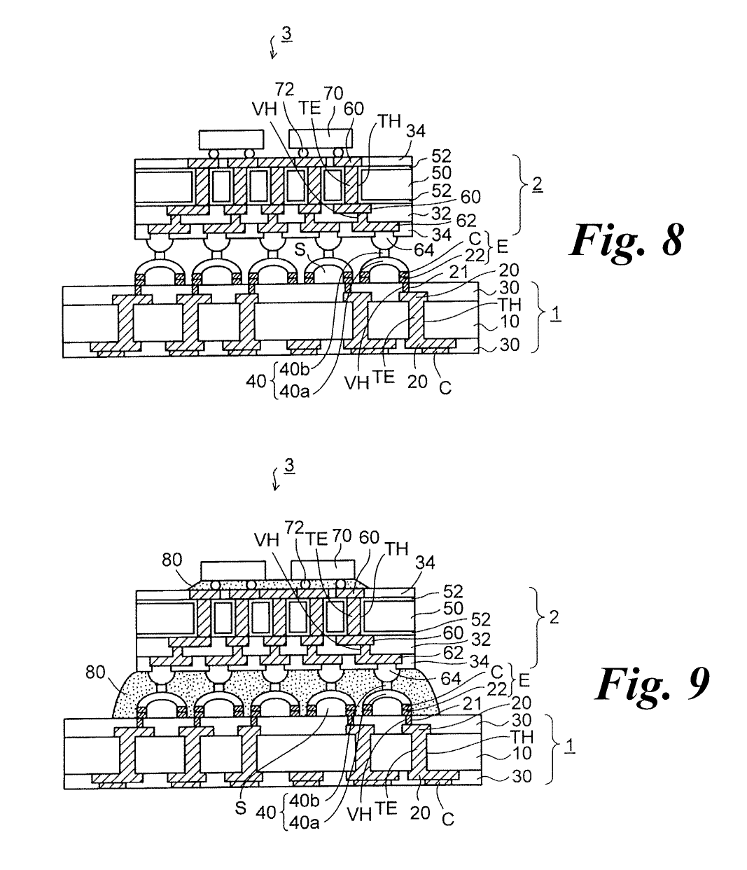

Then, as shown in FIG. 8, the external connection terminals 64 (solder balls) formed on the bottom surface of the semiconductor-chips-mounted interposer 2 (see FIG. 7B) are placed over the connection projections 40b of the respective flexible electrode terminals 40 of the mounting board 1 (see FIG. 6), and reflow soldering is performed by heating.

As a result, the semiconductor chips 70 are electrically connected to the mounting board 1 via the interposer 2. Thus, a semiconductor device 3 according to the first embodiment is obtained.

When heating is performed at the time of mounting, thermal stress occurs due to a mismatch between the thermal expansion coefficients of the mounting board 1 (made of a glass epoxy resin) and the interposer 2 (made of silicon). However, in the first embodiment, even if thermal stress occurs, the stress can be dispersed because the flexible electrode terminals 40 are warped through elastic deformation.

Therefore, residual stress occurring in the joining portions of the mounting board I and the interposer 2 can be weakened, thereby preventing destruction of a joining portion of the mounting board 1 and the interposer 2 and increasing reliability of the semiconductor device 3.

Where lead-free (Pb-free) solder such as tin-silver-copper (Sn—Ag—Cu) solder is used, heating needs to be performed at a relatively high temperature (about 220° C. to 250° C.). Even in such a case, by using the mounting board 1 according to the first embodiment which has the flexible electrode terminals 40, highly-reliable semiconductor devices 3 can be manufactured with a high yield.

That is, by using the mounting board 1 according to the first embodiment which has the flexible electrode terminals 40 having the stress reducing function, concentration of residual stress at the joining portions of the mounting board 1 and the interposer 2 can be prevented, and the reliability of the electrical connections of the semiconductor device 3 can be increased.

Furthermore, even if external mechanical stress acts on the joining portions of the mounting board 1 and the interposer 2, the stress can likewise be dispersed by warping of the flexible electrode terminals 40.

In the semiconductor device 3 according to the first embodiment, by using the mounting board 1 having the flexible electrode terminals 40, sufficient reliability of the joining portions can be secured even the spaces under the semiconductor chips 70 and the interposer 2 are not filled with underfill resin.

Of course, as necessary, as shown in FIG. 9, the spaces between the interposer 2 and the semiconductor chips 70 and the space between the interposer 2 and the mounting board 1 may be filled with underfill resin layers 80. Sealing the joining portions with the underfill resin layers 80 disperses stress further and hence can increase the reliability of the electrical connections further.

When the flexible electrode terminal 40 has the cruciform bulge 40a as shown in FIG. 5C or the rectangular bulge 40a as shown in FIG. 5D, the space under the flexible electrode terminal 40 can also be filled with the underfill resin. In the flexible electrode terminal 40 shown in FIG. 5B, a slit or hole may be formed in the circular bulge 40a in order to allow the underfill resin to pass therethrough.

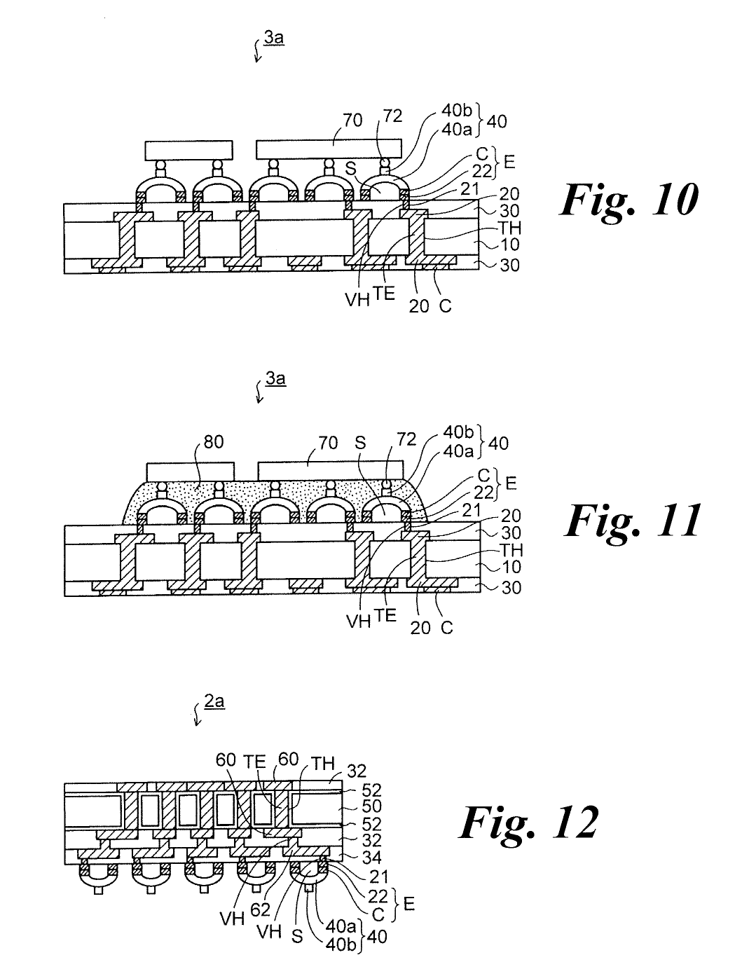

FIG. 10 shows a semiconductor device 3a in which solder bumps 72 of each semiconductor chip 70 are flip-chip-connected to the connection projections 40b of flexible electrode terminals 40 of the mounting board 1 shown in FIG. 6.

Also in this case, even if thermal stress occurs due to a mismatch between the thermal expansion coefficients of the mounting board 1 (made of a glass epoxy resin) and each semiconductor chip 70 (made of silicon) the stress can be dispersed because the flexible electrode terminals 40 warp and move.

This solves problems that a joining portion of the mounting board 1 and a semiconductor chip 70 is broken or elements of the semiconductor chip 70 are broken, and hence can increase the reliability of the electrical connections of the semiconductor device 3a.

Also in this case, as shown in FIG. 11, the spaces between the mounting board 1 and the semiconductor chips 70 may be filled with underfill resin layers 80.

In the examples of FIGS. 9 and 11, the spaces S between the flexible electrode terminals 40 and the underlying structure may also be filled with the underfill resin layer 80.

Although the flexible electrode terminals 40 are provided in the mounting board 1 in the above examples, as shown in FIG. 12, the flexible electrode terminals 40 may be provided in the interposer 2 shown in FIG. 7A, in place of the external connection terminals 64.

In an interposer 2a shown in FIG. 12, via holes VH are formed through the lower protective insulating layer 34 so as to reach the second wiring layer 62, as in FIG. 7A. The via holes VH are filled with respective via conductors 21.

Connection electrodes E each of which includes a conductor pattern layer 22 and a contact layer C are formed on the bottom surface of the lower protective insulating layer 34 so as to be connected to the respective via conductors 21. Flexible electrode terminals 40 are connected to the respective connection electrodes E in the same manner as in the mounting board 1.

As for the manufacture of the interposer 2a shown in FIG. 12, individual interposers 2a are obtained by executing individual manufacturing steps on a single silicon wafer, and then cutting the silicon wafer.

Thus, the flexible electrode terminals 40 are provided in the interposer 2a, as in the mounting board 1 of FIG. 6. Flexible electrode terminals 40 may also be connected to the upper first wiring layer 60 of the interposer 2a shown in FIG. 12.

Where the interposer 2a provided with the flexible electrode terminals 40 shown in FIG. 12 is connected to the mounting board 1, the mounting board 1 need not always be provided with the flexible electrode terminals 40. That is, the flexible electrode terminals 40 only need to be provided to one of the mounting board 1 and the interposer 2a.

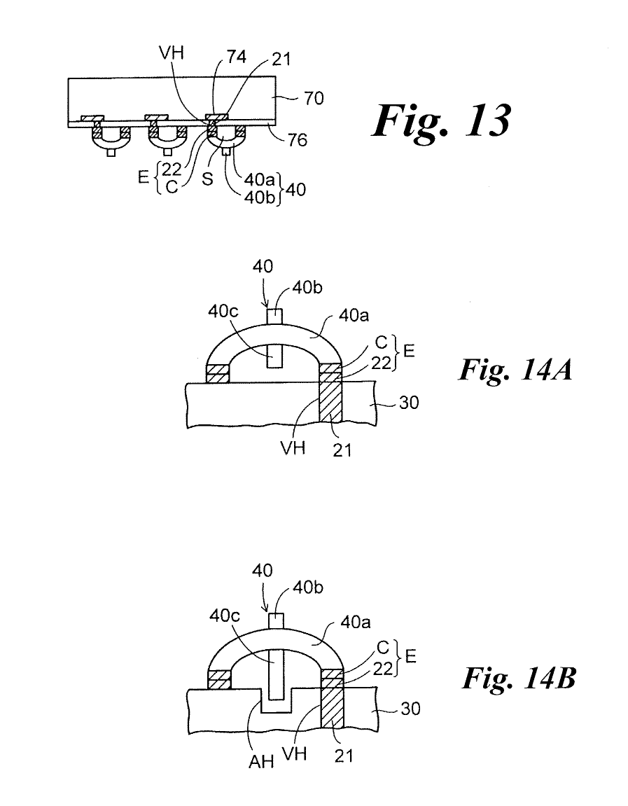

As shown in FIG. 13, flexible electrode terminals 40 may be provided in a semiconductor chip 70 instead of a wiring substrate (board) type electronic component such as a mounting board or an interposer.

In the semiconductor chip 70 shown in FIG. 13, a protective insulating layer 76 is formed on the bottom surface of the semiconductor chip 70 to have via holes VH which expose portions of electrode pads 74. Via conductors 21 are formed in the via holes VH so as to be connected to the connection pads 74, respectively.

Connection electrodes E which include a conductor pattern layer 22 and a contact layer C are formed on the bottom surface of the protective insulating layer 76 so as to be connected to the respective via conductors 21. Flexible electrode terminals 40 are connected to the respective connection electrodes E in the same manner as described above.

For example, individual silicon chips 70 are obtained by executing individual manufacturing steps on a single silicon wafer, and then cutting the silicon wafer.

Thus, the flexible electrode terminals 40 are provided in the semiconductor chip 70, as in the mounting board 1 of FIG. 6. Flexible electrode terminals 40 may be provided as external connection terminals in any of other various kinds of electronic components such as a capacitor, a resistor and an inductor, instead of a semiconductor chip.

The flexible electrode terminals 40 of the semiconductor chip 70 are connected to an interposer or a mounting board. Also in this case, the flexible electrode terminals 40 only need to be provided to one of the semiconductor chip 70 and the interposer or the mounting board.

FIGS. 14A and 14B illustrate a flexible electrode terminal according to modifications of the first embodiment. In FIG. 14A, a lower projection 40c is formed additionally at the center of the bottom surface of each flexible electrode terminal 40.

The lower projection 40c of the flexible electrode terminal 40 serves as a stopper which stops the movement of the flexible electrode terminal 40 because its tip hits the upper protective insulating layer 30 when the flexible electrode terminal 40 is pushed and moved downward.

In FIG. 14B, the upper protective insulating layer 30 of a mounting board or an interposer is formed with a positioning hole AH at a position corresponding to the lower projection 40c of the flexible electrode terminal 40, so that the lower projection 40c is insertable into the positioning hole AH. The connection electrode E is formed on the mounting board or the interposer.

In this case, the lower projection 40c is formed so as to extend past the bottom end of the bulge 40a.

The above flexible electrode terminal 40 can be easily placed on the connection electrode E, since the flexible electrode terminal 40 can easily be positioned by inserting its lower projection 40c into the positioning hole AH of the upper protective insulating layer 30. In particular, where the flexible electrode terminal 40 is swung into place using a jig, it can be placed over the connection electrode E efficiently with high accuracy.

### Embodiment 2

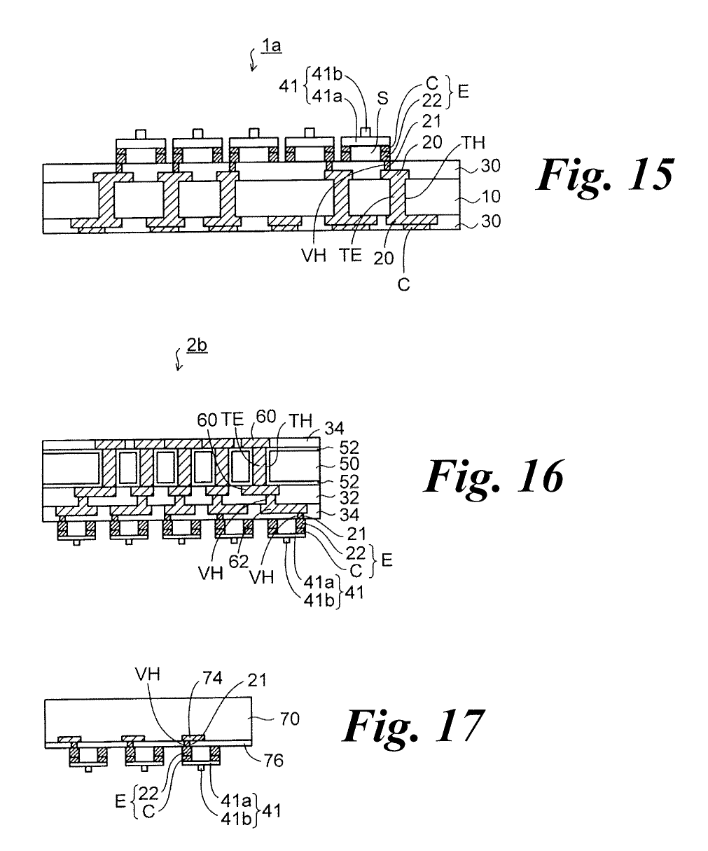

FIGS. 15-17 illustrate a mounting board, an interposer, and a semiconductor chip (electronic components) according to a second embodiment, respectively. In the second embodiment, the main body of each flexible electrode terminal is a flat plate. The other constituent elements are the same as in the first embodiment and hence will not be described in detail.

As shown in FIG. 15, each of flexible electrode terminals 41 provided in a mounting board 1a according to the second embodiment has a flat plate 41a (main body) and a connection projection 41b which is formed at the center of the top surface of the flat plate 41a. The flexible electrode terminals 41 are made of the same metal material as the flexible electrode terminals 40 used in the first embodiment.

An end portion of the flat plate 41a of each flexible electrode terminal 41 is connected to a connection electrode E. Since the flat plate 41a of each flexible electrode terminal 41 is not bulged upward, the height of the connection electrode E is set greater than in the first embodiment so secure a sufficient space S under the flat plate 41a. The height of the connection electrode E is set at about 20 to 50 μm, for example.

In the flexible electrode terminal 41 according to the second embodiment, as in the flexible electrode terminals 40 according to the first embodiment, stress can be concentrated at the connection projection 41b which is formed at the center of the top surface of the flat plate 41a. As a result, the stress is transmitted efficiently to the flat plate 41a via the connection projection 41b and can easily be dispersed because the flat plate 41a is warped through elastic deformation.

As shown in FIG. 16, as in the interposer 2a of FIG. 12, flexible electrode terminals 41 each having a flat plate 41a may be connected to respective connection electrodes E of an interposer 2b (electronic component).

As shown in FIG. 17, as in the semiconductor chip 70 of FIG. 13, flexible electrode terminals 41 each having a flat plate 41a may be connected to respective connection electrodes E of a semiconductor chip 70 (electronic component).

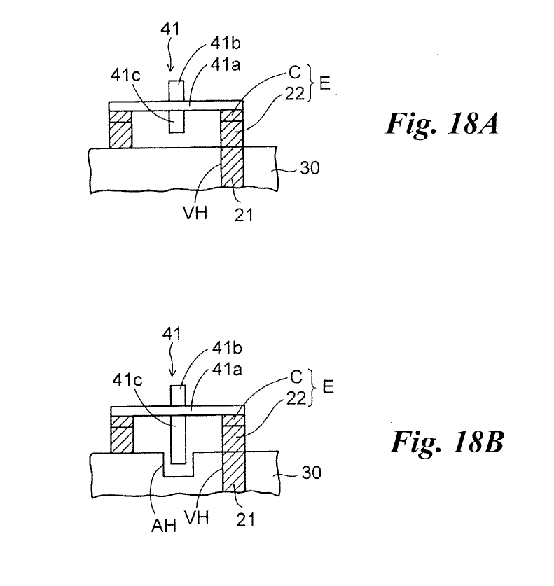

FIGS. 18A and 18B illustrate flexible electrode terminal according to modifications of the second embodiment. In FIG. 18A, as in each flexible electrode terminal 40 of FIG. 14A, a lower projection 40c is formed additionally at the center of the bottom surface of each flexible electrode terminal 41.

As in the flexible electrode terminal 40 of FIG. 14A, the lower projection 41c of the flexible electrode terminal 41 serves as a stopper which stops the movement of the flexible electrode terminal 41 when the flexible electrode terminal 41 is pushed and moved downward.

In FIG. 18B, as in each flexible electrode terminal 40 of FIG. 14B, the upper protective insulating layer 30 of a mounting board or an interposer is formed with a positioning hole AH at a position corresponding to the lower projection 41c of the flexible electrode terminal 41 so that the lower projection 41c is insertable into the positioning hole AH. As in the first embodiment, the flexible electrode terminal 41 can easily be positioned by inserting its lower projection 41c into the positioning hole AH of the upper protective insulating layer 30.

The connection electrode E is formed on the mounting board or the interposer.

Also in the second embodiment, as in the example of FIG. 8, the external connection terminals 64 of the interposer 2 to which the semiconductor chips 70 are flip-chip-connected are connected to the respective flexible electrode terminals 41 of the mounting board 1a.

Furthermore, as in the example of FIG. 10, the solder bumps 72 of each semiconductor chip 70 may be flip-chip-connected to respective flexible electrode terminals 41 of the mounting board 1a. Still further, the interposer 2b or the semiconductor chip 70 which is provided with the flexible electrode terminals 41 may be connected to a mounting board or an interposer.

The mounting board 1a, the interposer 2b and the semiconductor chip 70 according to the second embodiment which have the flexible electrode terminals 41 provide the same advantages as the mounting board 1, the interposer 2a and the semiconductor chip 70 according to the first embodiment, respectively.

The invention is not limited to the above described embodiments. For example, the above-described structure of the flexible electrode terminal 40 or 41 may be adaptable to a prove etc.

1. An electronic component comprising:
connection electrodes; and
flexible electrode terminals connected to the respective connection electrodes so that spaces are formed under the respective flexible electrode terminals, each flexible electrode terminal having a main body and a connection projection provided on a top surface of the main body, each flexible electrode terminal being elastically deformable when receiving pressure.

2. The electronic component of claim 1,
wherein the main body of the flexible electrode terminal is an upward bulge or a flat plate.

3. The electronic component of claim 1,
wherein the electronic component is a mounting board, an interposer, or a semiconductor chip.

4. The electronic component of claim 1,
wherein the flexible electrode terminals are connected to respective connection electrodes of a mounting board, and connection terminals of an interposer to which a semiconductor chip is flip-chip-connected are connected to the respective flexible electrode terminals.

5. The electronic component of claim 1,
wherein the flexible electrode terminals are connected to respective connection electrodes of a mounting board, and a semiconductor chip is flip-chip-connected to the respective flexible electrode terminals.

6. The electronic component of claim 1,
wherein the flexible electrode terminals are made of, phosphor bronze, beryllium copper, titanium copper, copper, or nickel.

7. The electronic component claim 1,
wherein each flexible electrode terminal further has a lower projection which is provided on a bottom surface of the main body.

8. The electronic component of claim 7,
wherein the connection electrodes are formed on a mounting board or an interposer which is formed with positioning holes, and the lower projections of the flexible electrode terminals are inserted in the positioning holes, respectively.

9. The electronic component of claim 1,
wherein each flexible electrode terminal is shaped like a circle, a cross, or a long and narrow rectangle in a plan view.

10. The electronic component of claim 4,
wherein the mounting board is an organic board containing a resin, and a substrate of the interposer is made of silicon.

11. A flexible electrode terminal comprising:
a main body; and
a connection projection provided on a top surface of the main body, the flexible electrode terminal being elastically deformable when receiving pressure.
